(19) United States
(12) Patent Application Publication
(10) Pub. No.: US 2023/0282628 A1
(43) Pub. Date: Sep. 7, 2023

(54) Ultraviolet (UV) Device Packaging Structure

(71) Applicant: Zhixin Semiconductor (Hangzhou) Co., Ltd., Hangzhou (CN)

(72) Inventors: Zhichao YAN, Hangzhou (CN); Xiaohui HUANG, Hangzhou (CN); Jianqing LIU, Hangzhou (CN); Dachao LI, Hangzhou (CN)

(21) Appl. No.: 18/116,542

(22) Filed: Mar. 2, 2023

(30) Foreign Application Priority Data
Mar. 4, 2022 (CN) 2022102052842

(51) Int. Cl. H01L 25/16; H01L 33/60; H01L 33/48

(52) U.S. Cl. CPC H01L 25/167; H01L 33/60; H01L 33/486

(57) ABSTRACT

Provided is an ultraviolet device packaging structure, including: a substrate, a light-emitting cup, a UV light-emitting diode (LED) chip, a protection chip, and a detection chip. The substrate is provided with a front surface circuit layer on a front surface and an electric bonding pad on a rear surface. An inner wall of the light-emitting cup is a light-concentrating reflecting surface. The light-emitting cup is open at both ends, one end of the light-emitting cup is a light-emitting port, and the other end is fixedly disposed on the front surface of the substrate. The UV LED chip, the protection chip, the detection chip are all disposed in a functional region of the front surface circuit layer. The detection chip and the protection chip are both located at a side of the UV LED chip that is away from the light-emitting port. A lens is fixedly disposed at the light-emitting port.

### CROSS-REFERENCE TO RELATED APPLICATION

This patent application claims the benefit and priority of Chinese Patent Application No. 2022102052842, filed with the China National Intellectual Property Administration on Mar. 04, 2022, the disclosure of which is incorporated by reference herein in its entirety as part of the present application.

### TECHNICAL FIELD

The present disclosure relates to the technical field of semiconductor packaging structures, and in particular, to an ultraviolet (UV) device packaging structure.

### BACKGROUND

An ultraviolet-C (UV-C) light-emitting diode (LED) has the advantages of high reliability, long service life, fast response, low power consumption, environmental protection, and small size. It is worth noting that radiation energy of TE light emission from a front surface of the UV-C LED chip is weaker than that of TM emission from a lateral surface. The material and structure of the UV-C LED chip result in a weak anti-static ability of the UV-C LED chip, and a special electrostatic discharge (ESD) protection LED chip needs to be connected in parallel to provide protection. In a conventional packaging structure, the protection LED chip is placed in parallel circuit of the UV LED chip, and is close to the UV-C LED chip, affecting light emission of the UV-C LED chip on a side corresponding to the protection LED chip, thus causing blocking and absorption.

In addition, UV-C LED chips, after being packaged into devices, are widely used in water disinfection, air disinfection, surface disinfection and other fields. In order to ensure the disinfection effect, it is necessary to continuously output a certain dose of UV-C radiation to achieve the disinfection and sterilization effect. With the growth of use time of the UV-C LED chip or due to environmental factors, radiation energy of light emitted by the LED chip will decay, and radiation energy becomes too low to achieve the UV-C radiation dose required for sterilization, thus reducing the quality of disinfection. Therefore, a new UV device packaging structure is urgently needed to solve the above problem.

### SUMMARY

In order to solve the above problems existing in the prior art, an objective of the present disclosure is to provide a UV device packaging structure, so as to improve light extraction efficiency and ensure a disinfection effect.

To achieve the foregoing objective, the present disclosure provides the following solution:

The present disclosure provides a UV device packaging structure, including:

a substrate, where the substrate is provided with a front surface circuit layer on a front surface and an electric bonding pad on a rear surface, and a functional region of the front surface circuit layer is interconnected with the electric bonding pad;

a light-emitting cup, where an inner wall of the light-emitting cup is a light-concentrating reflecting surface, the light-emitting cup is open at both ends, one end of the light-emitting cup is a light-emitting port, and the other end is fixedly disposed on the front surface of the substrate; and

a UV light-emitting diode (LED) chip, a protection chip, and a detection chip, where the UV LED chip, the protection chip, and the detection chip are all disposed in the functional region of the front surface circuit layer;

where the detection chip and the protection chip are both located at a side of the UV LED chip that faces away from the light-emitting port, the detection chip is configured to receive photons of UV light emitted by the UV LED chip and output the photons to an amplification circuit outside a device, and a lens is fixedly disposed at the light-emitting port.

Preferably, the front surface circuit layer includes a first functional region and a second functional region; the UV LED chip and the protection chip are disposed in the first functional region, and the detection chip is disposed in the second functional region; the first functional region and the second functional region are respectively interconnected with two different electric bonding pads through electroplated through-hole columns that are inserted and fixed in the substrate.

Preferably, the first functional region is provided with a clearance groove/hole, the second functional region is arranged in the clearance groove/hole, the first functional region is further provided with a mounting groove extending from a front surface to a rear surface of the first functional region, and the protection chip is disposed in the mounting groove.

Preferably, the clearance groove extends from an edge of the first functional region to the interior of the first functional region; cover plates are fixedly disposed on the mounting groove and the clearance groove respectively, a top surface of the cover plate and a top surface of the first functional region are in a same plane, and outer contours of the top surfaces of the two cover plates are consistent with two contours of the clearance groove and the mounting groove respectively; the cover plate is made of a high-reflective and high-UV-resistant material, and the UV light emitted by the UV LED chip enters the clearance groove from a lateral portion of the clearance groove after being reflected multiple times.

Preferably, the reflecting surface for reflecting light to the interior of the clearance groove is provided at an opening of the lateral portion of the clearance groove.

Preferably, an annular first limiting platform is disposed at an outer side of an end surface of the light-emitting cup on which the light-emitting port is provided; the lens is disposed in the first limiting platform and an outer surface of the lens abuts against an inner surface of the first limiting platform, and a bottom surface of the lens abuts against the end surface of the light-emitting cup; the lens is adhered to the end surface of the light-emitting cup and the inner surface of the first limiting platform through an adhesive.

Preferably, an annular second limiting platform is disposed at an inner side of an end surface of the light-emitting cup that is away from the light-emitting port; an outer contour of the second limiting platform is square; a third limiting platform matching the second limiting platform is disposed on the front surface of the substrate; the second limiting platform is located at an inner side of the third limiting platform; a top surface and an inner surface of the third limiting platform and the front surface of the substrate form a stepped mounting surface; an annular metal pad is fixedly laid on the mounting surface in advance, and the metal pad is a non-functional region of the front surface circuit layer; the light-emitting cup and the second limiting platform are each integrally formed and made of a metal material; bottom surfaces of the light-emitting cup and the second limiting platform are attached and soldered to the metal pad.

Preferably, an incident surface of the lens is a plane, and a light exit surface is a convex.

Preferably, the substrate is a ceramic substrate.

The present disclosure achieves the following technical effects over the prior art:

The UV device packaging structure provided by the present disclosure includes a detection chip. The detection chip is configured to receive photons of UV light emitted by the UV LED chip and transmit the photons to an amplification circuit outside the device, for further analysis and judgment, thereby achieving the objective of detecting in real time UV-C energy radiated by the UV LED chip. In this way, workers can replace a light-emitting device with insufficient radiation energy in time, to avoid inadequate disinfection due to insufficient radiation energy of the light-emitting device. In addition, both the detection chip and the protection chip are located at a side of the UV LED chip that faces away from the light-emitting port. The detection chip and the protection chip in this structure do not shield the lateral surface of the UV LED chip, and do not affect the light extraction efficiency of the UV LED chip. Therefore, the UV device packaging structure provided by the present disclosure can ensure high radiation energy of light emitted by the light-emitting device and high light extraction efficiency, thereby enhancing the disinfection effect for objects.

### BRIEF DESCRIPTION OF THE DRAWINGS

To describe the technical solutions in the embodiments of the present disclosure or in the prior art more clearly, the accompanying drawings required for the embodiments are briefly described below. Apparently, the accompanying drawings in the following description show merely some embodiments of the present disclosure, and a person of ordinary skill in the art may still derive other accompanying drawings from these accompanying drawings without creative efforts.

FIG. 1 is a cross-sectional view along one direction of a UV device packaging structure according to the present disclosure;

FIG. 2 is a cross-sectional view along another direction of a UV device packaging structure according to the present disclosure;

FIG. 3 is a cross-sectional view along another direction of a UV device packaging structure according to the present disclosure;

FIG. 4 is a schematic structural diagram of a UV device packaging structure without a lens according to the present disclosure;

FIG. 5 is a schematic structural diagram of a substrate, a light-emitting cup, a front surface circuit layer, and a UV LED chip in a UV device packaging structure according to the present disclosure;

FIG. 6 is a schematic structural diagram of a UV device packaging structure without a lens, a protection chip, and a detection chip according to the present disclosure;

FIG. 7 is a schematic structural diagram of a rear surface of a UV device packaging structure according to the present disclosure; and

FIG. 8 is a schematic structural diagram of two cover plates.

Reference numerals: 1: light-emitting cup; 11: first limiting platform; 2: lens; 3: substrate; 4: electric bonding pad; 5: front surface circuit layer; 51: first functional region; 511: mounting groove; 512: clearance groove; 52: non-functional region; 53: second functional region; 6: UV LED chip; 7: protection chip; 8: detection chip; 9: cover plate.

### DETAILED DESCRIPTION OF THE EMBODIMENTS

The technical solutions of the embodiments of the present disclosure are clearly and completely described below with reference to the accompanying drawings. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

In order to solve the problems existing in the prior art, an objective of the present disclosure is to provide a UV device packaging structure, so as to improve light extraction efficiency and ensure a disinfection effect.

To make the above-mentioned objective, features, and advantages of the present disclosure clearer and more comprehensible, the present disclosure will be further described in detail below in conjunction with the accompanying drawings and specific embodiments.

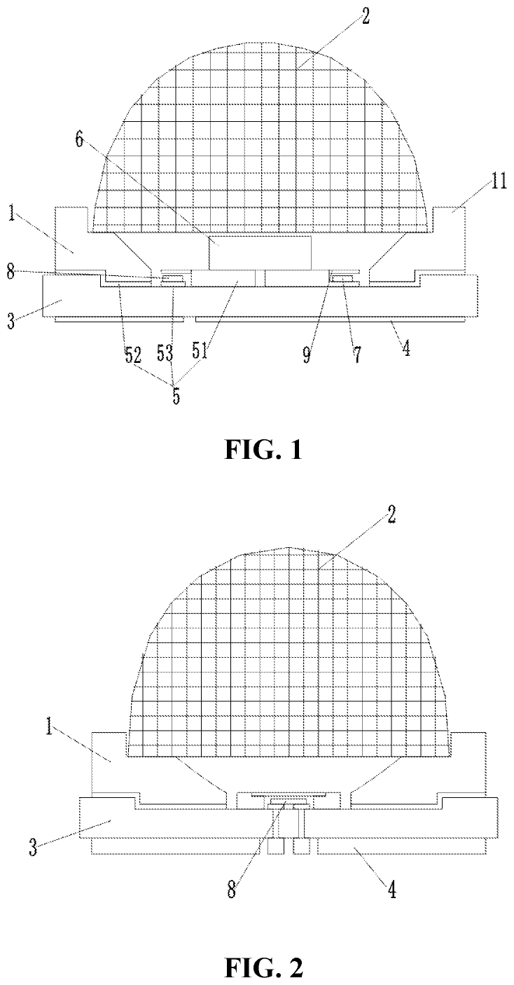

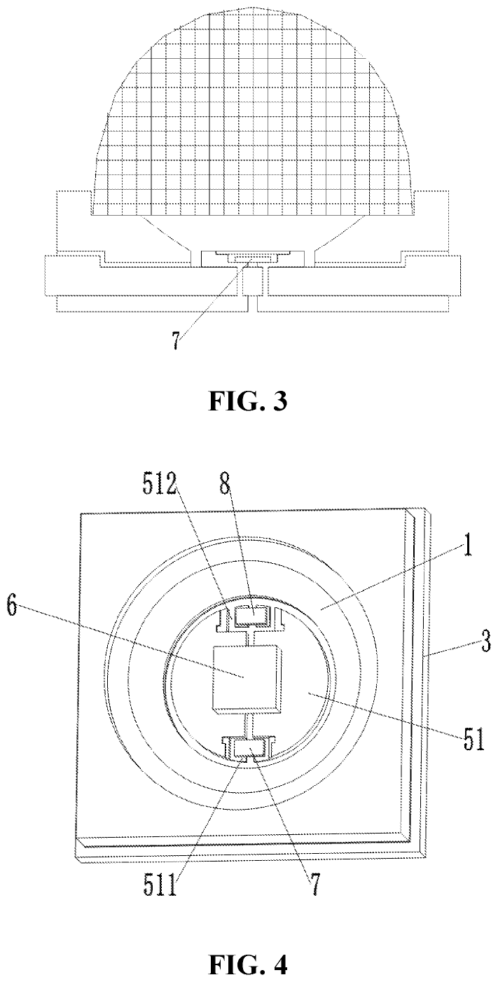

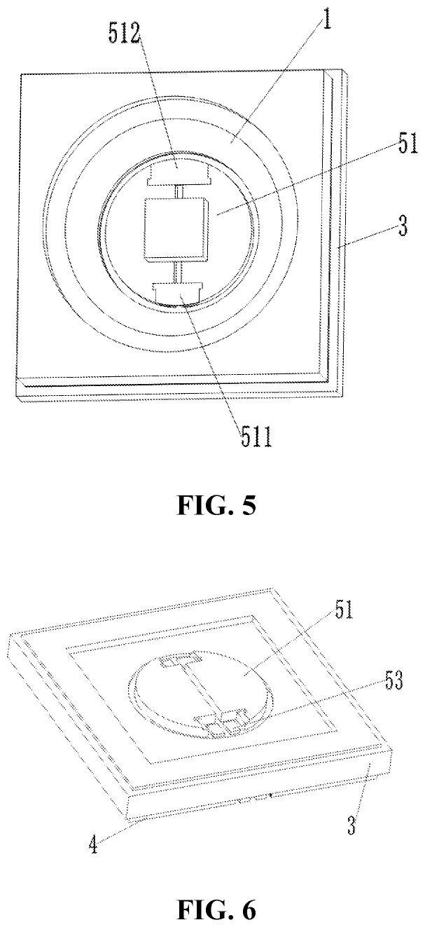

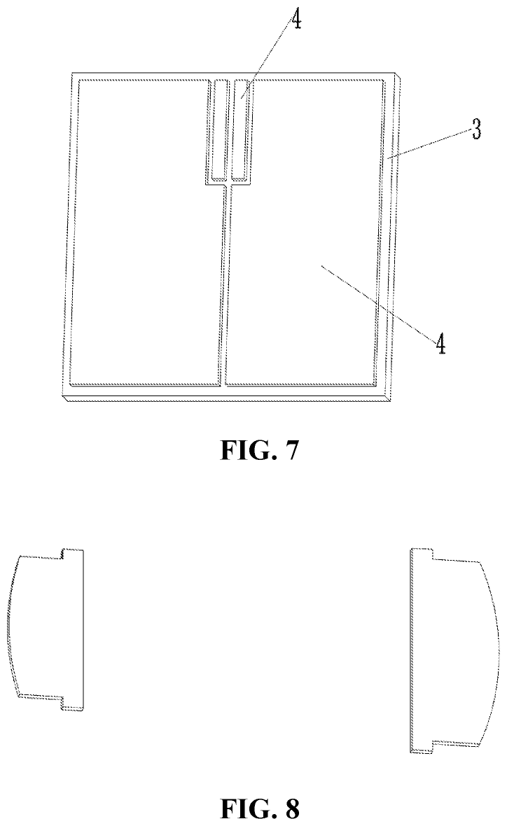

As shown in FIG. 1 to FIG. 8, the present disclosure provides a UV device packaging structure, including:

a substrate 3, where the substrate 3 is provided with a front surface circuit layer 5 on a front surface and an electric bonding pad 4 on a rear surface, and a functional region of the front surface circuit layer 5 is interconnected with the electric bonding pad 4;

a light-emitting cup 1, where an inner wall of the light-emitting cup 1 is a light-concentrating reflecting surface, the light-emitting cup 1 is open at both ends, one end of the light-emitting cup 1 is a light-emitting port, and the other end is fixedly disposed on the front surface of the substrate 3; and

a UV LED chip 6, a protection chip 7, and a detection chip 8, where the UV LED chip 6, the protection chip 7, and the detection chip 8 are all disposed in the functional region of the front surface circuit layer 5; the UV LED chip 6 is preferably a UV-C LED chip, which is an emitting end of UV-C light; the detection chip 8 is a receiving end of UV photons emitted by the UV-C LED chip; the protection chip 7, also known as a Zener diode chip, can provide electrostatic discharge (ESD for short) protection for the UV-C LED chip, and is also called an ESD protection LED chip.

The detection chip 8 and the protection chip 7 are both located at a side of the UV LED chip 6 that faces away from the light-emitting port. The detection chip 8 is configured to receive photons of UV light emitted by the UV LED chip 6, and a lens 2 is fixedly disposed at the light-emitting port.

The UV device packaging structure provided by the present disclosure includes a detection chip 8. The detection chip 8 is configured to receive photons of UV light emitted by the UV LED chip 6 and transmit the photons to an amplification circuit outside the device, for further analysis and judgment, thereby achieving the objective of detecting in real time UV-C energy radiated by the UV LED chip 6. In this way, workers can replace a light-emitting device with insufficient radiation energy in time, to avoid inadequate disinfection due to insufficient radiation energy of the light-emitting device. In addition, both the detection chip 8 and the protection chip 7 are located at a side of the UV LED chip 6 that faces away from the light-emitting port. The detection chip 8 and the protection chip 7 in this structure do not shield the lateral surface of the UV LED chip 6, and do not affect the light extraction efficiency of the UV LED chip. Therefore, the UV device packaging structure provided by the present disclosure can ensure high radiation energy of light emitted by the light-emitting device and high light extraction efficiency, thereby enhancing the disinfection effect for objects.

Further, the front surface circuit layer 5 includes a first functional region 51 and a second functional region 53. The UV LED chip 6 and the protection chip 7 are disposed in the first functional region 51. The detection chip 8 is disposed in the second functional region 53. The first functional region 51 and the second functional region 53 are respectively interconnected with two different electric bonding pads 4 through electroplated through-hole columns that are inserted and fixed in the substrate 3. The electric bonding pad 4 is a copper plated layer. Different electric bonding pads 4 are spaced apart, so as to be insulated from each other. An electric system of the detection chip 8 is configured independently. The electroplated through-hole column is formed in the following manner: a through hole structure is formed at a specified position on the front surface of the substrate 3 through laser perforation, and a copper column is formed by filling the through hole through metal plating. The electric bonding pad 4 and the front surface circuit layer 5 are each electroplated with a nickel-palladium-gold layer, where the gold layer is the outermost layer, the nickel layer is in contact with the copper layer, and the palladium layer is in the middle.

Further, the first functional region 51 is provided with a clearance groove/hole. The second functional region 53 is arranged in the clearance groove/hole. The first functional region 51 is further provided with a mounting groove 511 extending from a front surface to a rear surface of the first functional region 51, and the protection chip 7 is disposed in the mounting groove 511. The protection chip 7 and the detection chip 8 do not need to occupy extra positions, thereby improving the space utilization.

Further, the clearance groove 512 extends from an edge of the first functional region 51 to the interior of the first functional region 51. Cover plates 9 are fixedly disposed on the mounting groove 511 and the clearance groove 512 respectively. A top surface of the cover plate 9 and a top surface of the first functional region 51 are in a same plane, and outer contours of the top surfaces of the two cover plates 9 are consistent with two contours of the clearance groove 512 and the mounting groove 511 respectively. The cover plate 9 is made of a high-reflective and high-UV-resistant material, and the UV light emitted by the UV LED chip 6 enters the clearance groove 512 from a lateral portion of the clearance groove 512 after being reflected multiple times. The cover plates 9 can hide complex structures inside the clearance groove 512 and the mounting groove 511, to make the product more beautiful. Moreover, the cover plate 9 is made of a high-reflective and high-UV-resistant material, which is durable and capable of reflecting UV light, thereby improving the light extraction efficiency. In addition, the top surface of the first functional region 51 may be made of a metal material with high reflectivity, and specifically may be plated with a metal layer capable of reflecting light, to further improve the light extraction efficiency, thereby enhancing the disinfection effect.

Further, the cover plate 9 is fixedly adhered to the first functional region 51 through an adhesive.

Further, a reflecting surface that reflects light towards the interior of the clearance groove 512 is provided at the opening of the lateral portion of the clearance groove 512, such that the ultraviolet light can enter the clearance groove 512 and received by the detection chip 8.

Further, the cover plates 9 at the inner sides of the clearance groove 512 and the mounting groove 511 are each provided with two opposite lugs, as shown in the figure. The lugs can improve the stability of the cover plate 9.

Further, the vertical reflecting surface formed at the bottom of the light-emitting cup 1 can reflect UV-C light to the detection chip 8. The detection chip 8 receives and further integrates the UV-C light, to output the integrated UV-C light to the amplification circuit structure, thereby detecting in real time the UV-C energy radiated by the UV-C LED chip.

Further, an annular first limiting platform 11 is disposed at an outer side of an end surface of the light-emitting cup 1 on which the light-emitting port is provided. The lens 2 is disposed in the first limiting platform 11, and an outer surface of the lens 2 abuts against an inner surface of the first limiting platform 11. A bottom surface of the lens 2 abuts against the end surface of the light-emitting cup 1. The lens 2 is adhered to the end surface of the light-emitting cup 1 and the inner surface of the first limiting platform 11 through an adhesive.

Further, an annular second limiting platform is disposed at an inner side of an end surface of the light-emitting cup 1 that is away from the light-emitting port. An outer contour of the second limiting platform is square. A third limiting platform matching the second limiting platform is disposed on the front surface of the substrate 3. The second limiting platform is located at an inner side of the third limiting platform. A top surface and an inner surface of the third limiting platform and the front surface of the substrate 3 form a stepped mounting surface. An annular metal pad is fixedly laid on the mounting surface in advance, and the metal pad is a non-functional region 52 of the front surface circuit layer 5. The light-emitting cup 1 and the second limiting platform are each integrally formed and made of a metal material. Bottom surfaces of the light-emitting cup 1 and the second limiting platform are attached and soldered to the metal pad. The light-emitting cup 1 and the second limiting platform are soldered to the metal pad at a high temperature by using a metal solder.

Further, an incident surface of the lens 2 is a plane, and a light exit surface is a convex. The lens 2 has a light concentrating effect. An adhesive is evenly applied to a step surface of the light-emitting cup 1. The lens 2 is placed on the step to which the adhesive has been applied, and is uniformly pressed. A certain temperature is applied to fasten the lens 2 to the light-emitting cup 1. The lens 2 can concentrate and integrate UV-C light emitted by the UV-C LED chip, and also forms a protective sealed chamber for the UV-C LED chip, the detection chip 8, and the protection chip 7.

Further, the substrate 3 is a ceramic substrate.

Specific examples are used for illustration of the principles and implementations of the present disclosure. The description of the above embodiments is merely used to help understand the method and its core ideas of the present disclosure. In addition, those of ordinary skill in the art can make modifications in terms of specific implementations and scope of use according to the ideas of the present disclosure. In conclusion, the content of the present specification shall not be construed as limitations to the present disclosure.

What is claimed is:

1. An ultraviolet (UV) device packaging structure, comprising:
a substrate, wherein the substrate is provided with a front surface circuit layer on a front surface and an electric bonding pad on a rear surface, and a functional region of the front surface circuit layer is interconnected with the electric bonding pad;
a light-emitting cup, wherein an inner wall of the light-emitting cup is a light-concentrating reflecting surface, the light-emitting cup is open at both ends, one end of the light-emitting cup is a light-emitting port, and the other end is fixedly disposed on the front surface of the substrate; and
a UV light-emitting diode (LED) chip, a protection chip, and a detection chip, wherein the UV LED chip, the protection chip, and the detection chip are all disposed in the functional region of the front surface circuit layer;
wherein the detection chip and the protection chip are both located at a side of the UV LED chip that faces away from the light-emitting port, the detection chip is configured to receive photons of UV light emitted by the UV LED chip and output the photons to an amplification circuit outside a device, and a lens is fixedly disposed at the light-emitting port.

2. The UV device packaging structure according to claim 1, wherein the front surface circuit layer comprises a first functional region and a second functional region; the UV LED chip and the protection chip are disposed in the first functional region, and the detection chip is disposed in the second functional region; the first functional region and the second functional region are respectively interconnected with two different electric bonding pads through electroplated through-hole columns that are inserted and fixed in the substrate.

3. The UV device packaging structure according to claim 2, wherein the first functional region is provided with a clearance groove/hole, the second functional region is arranged in the clearance groove/hole, the first functional region is further provided with a mounting groove extending from a front surface to a rear surface of the first functional region, and the protection chip is disposed in the mounting groove.

4. The UV device packaging structure according to claim 3, wherein the clearance groove extends from an edge of the first functional region to the interior of the first functional region; cover plates are fixedly disposed on the mounting groove and the clearance groove respectively, a top surface of the cover plate and a top surface of the first functional region are in a same plane, and outer contours of the top surfaces of the two cover plates are consistent with two contours of the clearance groove and the mounting groove respectively; the cover plate is made of a high-reflective and high-UV-resistant material, and the UV light emitted by the UV LED chip enters the clearance groove from a lateral portion of the clearance groove after being reflected multiple times.

5. The UV device packaging structure according to claim 4, wherein the reflecting surface for reflecting light to the interior of the clearance groove is provided at an opening of the lateral portion of the clearance groove.

6. The UV device packaging structure according to claim 1, wherein an annular first limiting platform is disposed at an outer side of an end surface of the light-emitting cup on which the light-emitting port is provided; the lens is disposed in the first limiting platform, and an outer surface of the lens abuts against an inner surface of the first limiting platform; a bottom surface of the lens abuts against the end surface of the light-emitting cup; the lens is adhered to the end surface of the light-emitting cup and the inner surface of the first limiting platform through an adhesive.

7. The UV device packaging structure according to claim 6, wherein an annular second limiting platform is disposed at an inner side of an end surface of the light-emitting cup that is away from the light-emitting port; an outer contour of the second limiting platform is square; a third limiting platform matching the second limiting platform is disposed on the front surface of the substrate; the second limiting platform is located at an inner side of the third limiting platform; a top surface and an inner surface of the third limiting platform and the front surface of the substrate form a stepped mounting surface; an annular metal pad is fixedly laid on the mounting surface in advance, and the metal pad is a non-functional region of the front surface circuit layer; the light-emitting cup and the second limiting platform are each integrally formed and made of a metal material; bottom surfaces of the light-emitting cup and the second limiting platform are attached and soldered to the metal pad.

8. The UV device packaging structure according to claim 1, wherein an incident surface of the lens is a plane, and a light exit surface is a convex.

9. The UV device packaging structure according to claim 2, wherein an incident surface of the lens is a plane, and a light exit surface is a convex.

10. The UV device packaging structure according to claim 3, wherein an incident surface of the lens is a plane, and a light exit surface is a convex.

11. The UV device packaging structure according to claim 4, wherein an incident surface of the lens is a plane, and a light exit surface is a convex.

12. The UV device packaging structure according to claim 5, wherein an incident surface of the lens is a plane, and a light exit surface is a convex.

13. The UV device packaging structure according to claim 6, wherein an incident surface of the lens is a plane, and a light exit surface is a convex.

14. The UV device packaging structure according to claim 7, wherein an incident surface of the lens is a plane, and a light exit surface is a convex.

15. The UV device packaging structure according to claim 1, wherein the substrate is a ceramic substrate.

16. The UV device packaging structure according to claim 2, wherein the substrate is a ceramic substrate.

17. The UV device packaging structure according to claim 3, wherein the substrate is a ceramic substrate.

18. The UV device packaging structure according to claim 4, wherein the substrate is a ceramic substrate.

19. The UV device packaging structure according to claim 5, wherein the substrate is a ceramic substrate.

20. The UV device packaging structure according to claim 6, wherein the substrate is a ceramic substrate.
